(19) United States
(12) Patent Application Publication
(10) Pub. No.: US 2025/0351884 A1
(43) Pub. Date: Nov. 20, 2025

(54) AEROSOL-GENERATING DEVICE AND OPERATION METHOD THEREOF

(71) Applicant: KT&G CORPORATION, Daejeon (KR)

(72) Inventor: Jaemin LEE, Siheung-si Gyeonggi-do (KR)

(73) Assignee: KT&G CORPORATION, Daejeon (KR)

(21) Appl. No.: 19/208,466

(22) Filed: May 14, 2025

(30) Foreign Application Priority Data
May 14, 2024 (KR) 10-2024-0063456

(51) Int. Cl. A24F 40/53; A24F 40/20; A24F 40/465; A24F 40/51; A24F 40/57; A24F 40/60; A24F 40/65

(52) U.S. Cl. CPC A24F 40/53; A24F 40/51; A24F 40/57; A24F 40/20; A24F 40/465; A24F 40/60; A24F 40/65

(57) ABSTRACT

Disclosed are an aerosol-generating device and a method of operating the same. The aerosol-generating device includes a body having an insertion space formed therein, a heater configured to heat a stick inserted into the insertion space, a sensor configured to output a sensing value corresponding to capacitance of the insertion space, a memory, and a controller, wherein the controller is configured to store the sensing value in the memory according to a predetermined cycle, to calculate a representative value of a plurality of consecutive sensing values stored in the memory, to calculate a delta value, which is the difference between two consecutive representative values, to determine whether the stick is inserted based on the sum of a predetermined number of consecutive delta values, and in response to insertion of the stick, to adjust the supply of power to the heater based on a change in the delta value.

### CROSS-REFERENCE TO RELATED APPLICATION

Pursuant to 35 U.S.C. § 119 (a), this application claims the benefit of earlier filing date and right of priority to Korean Patent Application No. 10-2024-0063456, filed on May 14, 2024, the contents of which are hereby incorporated by reference herein in its entirety.

### BACKGROUND OF THE DISCLOSURE

### 1. Field of the Disclosure

The present disclosure relates to an aerosol-generating device and an operation method thereof.

### 2. Description of the Related Art

An aerosol-generating device is a device that extracts certain components from a medium or a substance by generating an aerosol. The medium may contain a multicomponent substance. The substance contained in the medium may be a multicomponent flavoring substance. For example, the substance contained in the medium may include a nicotine component, an herbal component, and/or a coffee component. Recently, various studies on aerosol-generating devices have been conducted.

Generally, internal heating, external heating, and induction heating using an induction coil and a susceptor are used to heat an aerosol-generating substance contained in a stick. In addition, although it is common for an aerosol-generating device to heat a single substance (or region) in order to generate an aerosol, in recent years, a method of heating a plurality of substances (or a plurality of regions) together to generate an aerosol in order to improve the sense of taste and to increase the atomization amount has also been used.

Conventionally, the state of the stick is determined by determining whether the difference between sensing values of a sensor is greater than or equal to a certain level or using the average of sensing values for a certain period of time. However, according to the conventional method, if noise occurs in the sensing values of the sensor, the difference between the sensing values or the average of the sensing values may temporarily change significantly due to the noise, which may significantly reduce the accuracy of determining the state of the stick. In addition, there is a problem that it is difficult to consider various patterns of a user who uses the stick, such as slowly inserting or removing the stick or adjusting the position of the stick while inserting a part of the stick and then inserting the remaining part of the stick.

### SUMMARY OF THE DISCLOSURE

It is an object of the present disclosure to solve the above and other problems.

It is another object of the present disclosure to provide an aerosol-generating device capable of accurately determining the state of a stick using sensing values of a sensor and a method of operating the same.

It is still another object of the present disclosure to provide an aerosol-generating device capable of adjusting the supply of power to a heater based on the state of an insertion space into which the stick is inserted and a method of operating the same.

It is still another object of the present disclosure to provide an aerosol-generating device capable of optimizing criteria for determining the state of the stick based on the pattern of a user who uses the stick and a method of operating the same.

In accordance with an aspect of the present disclosure for accomplishing the above objects, an aerosol-generating device includes a body having an insertion space formed therein, a heater configured to heat a stick inserted into the insertion space, a sensor configured to output a sensing value corresponding to capacitance of the insertion space, a memory, and a controller, wherein the controller is configured to store the sensing value in the memory according to a predetermined cycle, to calculate a representative value of a plurality of consecutive sensing values stored in the memory, to calculate a delta value, which is the difference between two consecutive representative values, to determine whether the stick is inserted based on the sum of a predetermined number of consecutive delta values, and in response to insertion of the stick, to adjust the supply of power to the heater based on a change in the delta value.

In accordance with another aspect of the present disclosure for accomplishing the above objects, a method of operating an aerosol-generating device includes storing a sensing value corresponding to the capacitance of an insertion space in a memory according to a predetermined cycle, calculating a representative value of a plurality of consecutive sensing values stored in the memory, calculating a delta value, which is the difference between two consecutive representative values, determining whether a stick is inserted based on the sum of a predetermined number of consecutive delta values, and in response to insertion of the stick, adjusting the supply of power to a heater based on a change in the delta value.

### BRIEF DESCRIPTION OF THE DRAWINGS

FIG. 1 is a view showing an aerosol-generating device according to one embodiment of the present disclosure.

FIG. 2 is a view showing an aerosol-generating device according to according to another embodiment of the present disclosure.

FIG. 3 is a view showing an aerosol-generating device according to according to another embodiment of the present disclosure.

FIG. 4 is a front perspective view of an aerosol-generating device according to an embodiment of the present disclosure;

FIG. 5 is an exploded sectional view of an upper case, a body, and a heater holder of the aerosol-generating device according to the embodiment of the present disclosure;

FIG. 6 is a coupled sectional view of the upper case, the body, and the heater holder of the aerosol-generating device according to the embodiment of the present disclosure;

FIG. 7 is a sectional view of the heater holder of the aerosol-generating device according to the embodiment of the present disclosure;

FIG. 8 is a block diagram of the aerosol-generating device according to one embodiment of the present disclosure.

FIG. 9 is a flowchart showing a method of operating an aerosol-generating device according to an embodiment of the present disclosure;

FIG. 10 is a view referenced in the description of data stored in a memory of the aerosol-generating device according to the embodiment of the present disclosure;

FIG. 11 is a graph showing a signal from a stick detection sensor when a stick is inserted in accordance with an embodiment of the present disclosure;

FIG. 12 is a graph showing a signal from the stick detection sensor when a part of the stick is inserted and then removed in accordance with the embodiment of the present disclosure;

FIG. 13 is a graph showing a signal from the stick detection sensor when the stick is inserted in accordance with another embodiment of the present disclosure;

FIG. 14 is a flowchart showing a method of operating an aerosol-generating device according to another embodiment of the present disclosure; and

FIG. 15 is a graph showing a signal from the stick detection sensor when the stick is inserted in accordance with an embodiment of the present disclosure.

### DETAILED DESCRIPTION OF THE PREFERRED EMBODIMENTS

Hereinafter, the embodiments of the present disclosure will be described in detail with reference to the accompanying drawings, the same or similar elements are denoted by the same reference numerals even though they are depicted in different drawings, and redundant descriptions thereof will be omitted.

In the following description, with respect to constituent elements used in the following description, the suffixes “module” and “unit” are used only in consideration of facilitation of description, and do not have mutually distinguished meanings or functions.

In addition, in the following description of the embodiments of the present disclosure, a detailed description of known functions and configurations incorporated herein will be omitted when the same may make the subject matter of the embodiments of the present disclosure rather unclear. In addition, the accompanying drawings are provided only for a better understanding of the embodiments of the present disclosure and are not intended to limit the technical ideas of the present disclosure. Therefore, it should be understood that the accompanying drawings include all modifications, equivalents, and substitutions within the scope and sprit of the present disclosure.

It will be understood that although the terms “first”, “second”, etc., may be used herein to describe various components, these components should not be limited by these terms. These terms are only used to distinguish one component from another component.

It will be understood that when a component is referred to as being “connected to” or “coupled to” another component, it may be directly connected to or coupled to another component, or intervening components may be present. On the other hand, when a component is referred to as being “directly connected to” or “directly coupled to” another component, it is to be understood that there are no intervening components present.

As used herein, the singular forms are intended to include the plural forms as well, unless the context clearly indicates otherwise.

Throughout the following description, the direction of an aerosol-generating device and a cartridge may be defined based on an orthogonal coordinate system. In the orthogonal coordinate system, an x-axis direction may be defined as the leftward or rightward direction of the aerosol-generating device and the cartridge. A y-axis direction may be defined as the forward or rearward direction of the aerosol-generating device and the cartridge. A z-axis direction may be defined as the upward or downward direction of the aerosol-generating device and the cartridge.

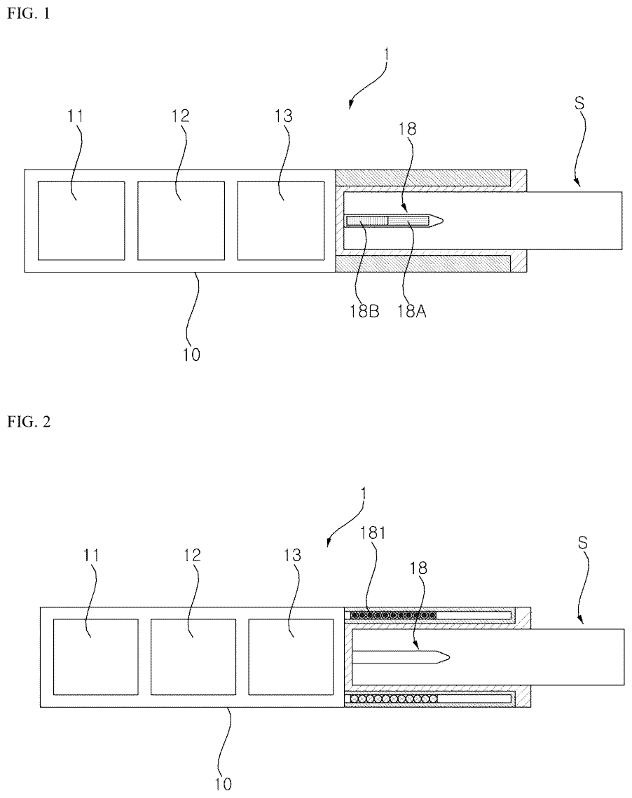

FIGS. 1 to 3 are views showing an aerosol-generating device according to various embodiments of the present disclosure.

Referring to FIG. 1, an aerosol-generating device according to embodiments of the present disclosure may include at least one of a power supply 11, a controller 12, a sensor 13, or a heater 18. At least one of the power supply 11, the controller 12, the sensor 13, or the heater 18 may be disposed in a body 10 of the aerosol-generating device. The body 10 may define a space having an open top to allow a stick S, which is an aerosol-generating article, to be inserted thereinto. The space having an open top may be referred to as an insertion space. The insertion space may be formed so as to be depressed to a predetermined depth toward the interior of the body 10 so that the stick S is inserted at least partway thereinto. The depth of the insertion space may correspond to the length of the portion of the stick S that contains an aerosol-generating substance and/or medium. The lower end of the stick S may be inserted into the body 10, and the upper end of the stick S may protrude to the outside of the body 10. A user may inhale air in a state of holding the upper end of the stick S, which is exposed to the outside, in the mouth.

The heater 18 may heat the stick S. The heater 18 may be elongated upward in the space into which the stick S is inserted. For example, the heater 18 may include a tube-type heating element, a plate-type heating element, a needle-type heating element, or a rod-type heating element. The heater 18 may be inserted into a lower portion of the stick S. The heater 18 may include an electro-resistive heater and/or an induction heater.

For example, referring to FIG. 1, the heater 18 may be a resistive heater. For example, the heater 18 may be electrically connected to the power supply 11. The heater 18 may directly generate heat using current received from the power supply 11.

For example, a hollow space may be formed inside the heater 18. An electrically conductive track and/or a temperature sensor may be mounted in the hollow space of the heater 18. The electrically conductive track may be supplied with current from the power source 11 and may be heated, and the heater 18 may be heated by the heat generated from the electrically conductive track.

For example, the heater 18 may include multiple heaters. The heater 18 may include a first heater 18A and a second heater 18B. The first and second heaters 18A and 18B may be disposed in series in a longitudinal direction. The first and second heaters 18A and 18B may be heated sequentially or simultaneously.

For example, referring to FIG. 2, the aerosol-generating device may include an induction coil 181 surrounding the heater 18. The induction coil 181 may cause the heater 18 to generate heat. The heater 18 as a susceptor may generate heat using a magnetic field generated by alternating current flowing through the induction coil 181. The magnetic field may pass through the heater 18 to generate an eddy current in the heater 18. The current may cause the heater 18 to generate heat.

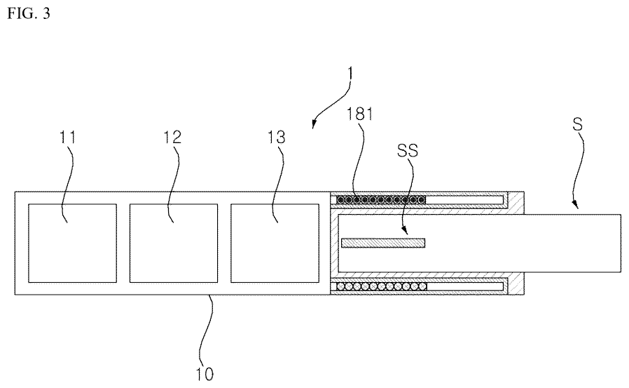

For example, referring to FIG. 3, a susceptor SS may be included in the stick S, and the susceptor SS in the stick S may generate heat using a magnetic field generated by alternating current flowing through the induction coil 181. The susceptor SS may be disposed in the stick S and may not be electrically connected to the aerosol-generating device. The susceptor SS may be inserted into the insertion space together with the stick S and may be removed from the insertion space together with the stick S. The stick S may be heated by the susceptor SS in the stick S.

The power supply 11 may supply power so that components of the aerosol-generating device operate. The power supply 11 may be referred to as a battery. The power supply 11 may supply power to at least one of the controller 12, the sensor 13, or the heater 18. The power supply 11 may supply power to the induction coil 181.

The controller 12 may control overall operation of the aerosol-generating device. The controller may be mounted on a printed circuit board (PCB). The controller 12 may control operation of at least one of the power supply 11, the sensor 13, or the heater 18. The controller 12 may control operation of the induction coil 181. The controller 12 may control operation of a display, a motor, etc. mounted in the aerosol-generating device. The controller 12 may check the state of each of the components of the aerosol-generating device and may determine whether the aerosol-generating device is in an operable state.

The controller 12 may analyze a result of detection by the sensor 13 and may control subsequent processes. For example, the controller 12 may control, based on a result of detection by the sensor 13, power supplied to the heater 18 so that operation of the heater 18 commences or ends. For example, the controller 12 may control, based on a result of detection by the sensor 13, the amount of power supplied to the heater 18 and a power supply time so that the heater 18 is heated to a predetermined temperature or is maintained at an appropriate temperature.

The sensor 13 may include at least one of a temperature sensor, a puff sensor, an stick detection sensor, or an acceleration sensor. For example, the sensor 13 may detect at least one of the temperature of the heater 18, the temperature of the power supply 11, or the internal/external temperature of the body 10. For example, the sensor 13 may detect a user puff. For example, the sensor 13 may detect whether the stick S is inserted into the insertion space. For example, the sensor 13 may detect movement of the aerosol-generating device.

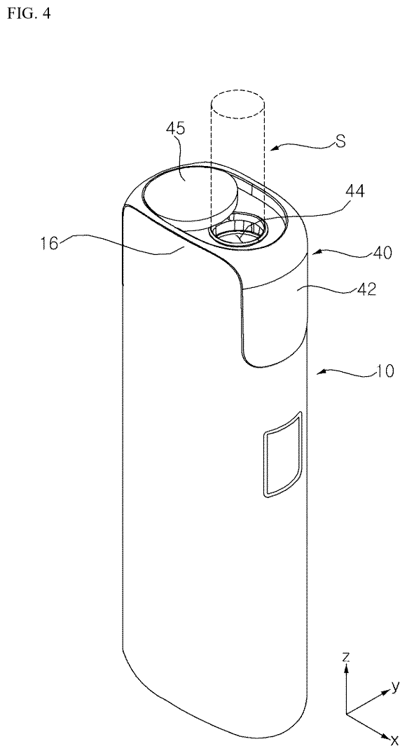

FIG. 4 is a front perspective view of the aerosol-generating device according to one embodiment of the present disclosure.

Referring to FIG. 4, an upper case 40 may be detachably coupled to the body 10. The upper case 40 may be coupled to the upper part of the body 10. The upper case 40 may cover the periphery of the upper part of the body 10. The upper case 40 may have an insertion hole 44. The stick S may be inserted into the insertion hole 44. The upper case 40 may include a cap 45 that opens and closes the insertion hole 44. The cap 45 may slide laterally to open and close the insertion hole 44.

The upper case 40 may include upper case wings 42. The upper case wings 42 may extend downward from both sides of an upper case body 41.

The body 10 may include body wings 16. The body wings 16 may extend upward from the edge of the upper part of the body 10. The body wings 16 may be formed as a pair so as to face each other with respect to the upper part of the body 10. The body wings 16 may be formed at positions that are misaligned with the upper case wings 42.

When the upper case 40 is coupled to the body 10, the upper case 40 may form the appearance of the upper part of the aerosol-generating device. When the upper case 40 is coupled to the body 10, the body wings 16 may cover the side parts of the upper case 40 exposed between the upper case wings 42. When the upper case 40 is coupled to the body 10, the upper case wings 42 may cover an outer lateral wall of the body 10.

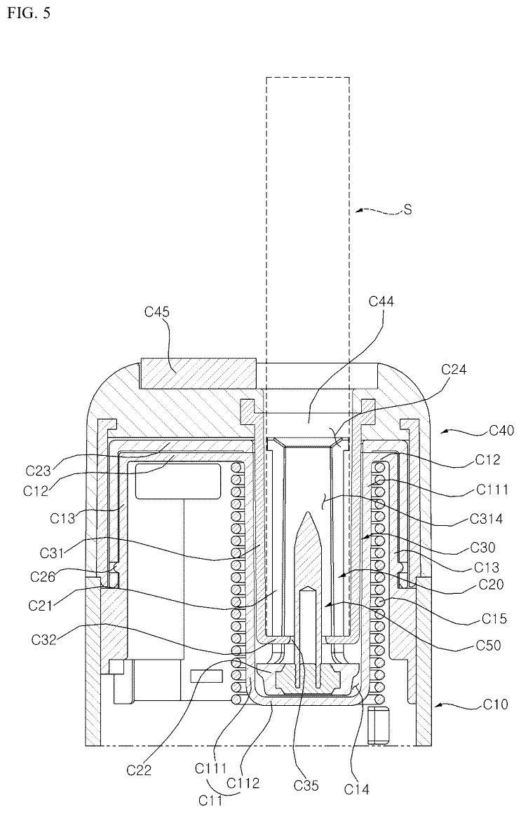

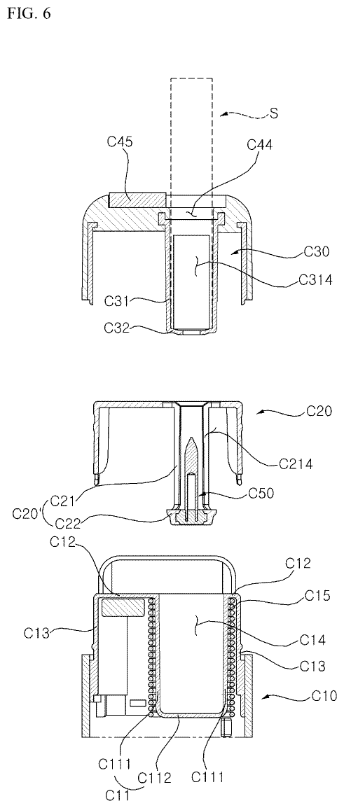

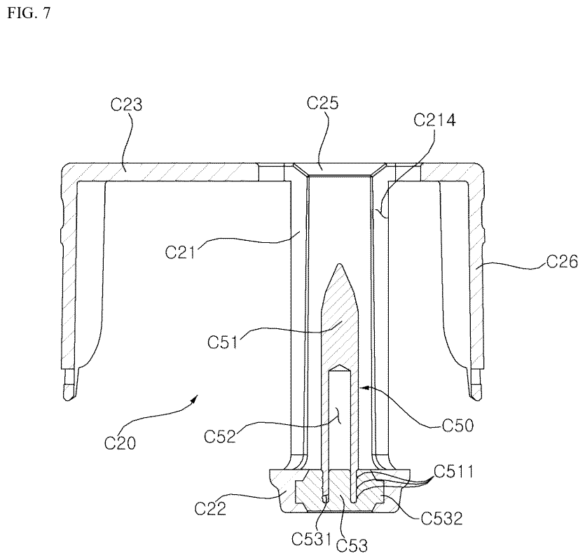

FIG. 5 is an exploded sectional view of an upper case, a body, and a heater holder of the aerosol-generating device according to the embodiment of the present disclosure, FIG. 6 is a coupled sectional view of the upper case, the body, and the heater holder of the aerosol-generating device according to the embodiment of the present disclosure, and FIG. 7 is a sectional view of the heater holder of the aerosol-generating device according to the embodiment of the present disclosure.

Referring to FIGS. 5 and 6, the body C10 of the aerosol-generating device according to the embodiment of the present disclosure may have a shape which extends vertically. The body C10 may be provided with a first insertion space C14 formed therein. The first insertion space C14 may be open upward. The first insertion space C14 may have a cylindrical shape that extends vertically. The first insertion space C14 may be defined by a body pipe C11 formed in the body C10. The body pipe C11 may include a lateral wall C111 surrounding the perimeter of the first insertion space C14, and a lower wall C112 covering the bottom of the first insertion space C14. The lower wall C112 may be formed on the bottom of the body pipe C11. The lateral wall C111 of the body pipe C11 may be referred to as an inner lateral wall C111 of the body C10.

The heater holder C20 and the extractor C30 may be separably inserted into the first insertion space C14. A pipe C20′ may include a lateral wall C21 that extends upward and downward and a lower wall C22 formed at a lower end of the lateral wall C21. The lower wall C22 of the pipe C20′ may be named a bottom C22 or a mount C22. The lower wall C22 of the pipe C20′ may form the bottom C22 of the heater holder C20. A heater C50 may be coupled or fixed to the heater holder C20.

The lateral wall C21 of the heater holder C20 and a lateral wall C31 of the extractor C30 may define a second insertion space C24 that is opened upward. Each of the lateral wall C21 of the heater holder C20 and the lateral wall C31 of the extractor C30 may cover at least one side of the second insertion space C24. The lateral wall C21 of the heater holder C20 and the lateral wall C31 of the extractor C30 may form a side circumference of the second insertion space C24.

The lateral wall C31 of the extractor C30 may extend upward and downward. The lateral wall C21 of the heater holder C20 and the lateral wall C31 of the extractor C30 may be spaced apart from the center of the second insertion space C24 by the same distance in a radial direction. The lateral wall C21 of the heater holder C20 and the lateral wall C31 of the extractor C30 may be located on the same circumference extension line of the second insertion space C24. Each of the lateral wall C21 of the heater holder C20 and the lateral wall C31 of the extractor C30 may extend along the circumference of the second insertion space C24 in a curved manner in a circumferential direction.

The lateral wall C21 of the heater holder C20 may be provided in plural so as to be disposed along the circumference of the lower wall C22 of the heater holder C20. A first slit C214 that extends upward and downward may be formed between adjacent ones of the plurality of lateral walls C21 of the heater holder C20. The plurality of lateral walls C21 of the heater holder C20 and the plurality of first slits C214 may be alternately disposed along the circumference of the second insertion space C24 in the circumferential direction.

The lateral wall C31 of the extractor C30 may be provided in plural so as to be disposed along the circumference of the lower wall C32 of the extractor C30. A second slit C314 that extends upward and downward may be formed between adjacent ones of the plurality of lateral walls C31 of the extractor C30. The plurality of lateral walls C31 of the extractor C30 and the plurality of second slits C314 may be alternately disposed along the circumference of the second insertion space C24 in the circumferential direction.

The extractor C30 may be inserted into the heater holder C20. When the extractor C30 is inserted into the heater holder C20, the lateral wall C21 of the heater holder C20 may be disposed in the second slit C314, and the lateral wall C31 of the extractor C30 may be disposed in the first slit C214.

Accordingly, the lateral wall C21 of the heater holder C20 and the lateral wall C31 of the extractor C30 may form the second insertion space C24. Heat-generating efficiency of the heater C50 may be improved by reducing the thickness of the wall between an induction coil C15 and the heater C50.

The lower end of the stick S may be inserted into the second insertion space C24, and the upper end of the stick S may protrude outside the aerosol-generating device. The heater C50 may heat the first insertion space C14 and the second insertion space C24. The heater C50 may heat the stick S inserted into the second insertion space C24.

A lower end of the heater C50 may be fixed to the mount C22. The heater C50 may extend toward the opening of the second insertion space C24. The heater C50 may be formed in a cylindrical shape, and an upper end of the heater may be pointed upward. As another example, the heater C50 may have a shape extending in the circumferential direction and may be coupled to the lateral wall C21 of the heater holder C20. However, this is an example, and the shape of the heater C50 is not limited to what is described or shown as long as the heater is coupled to the heater holder C20 to heat the stick S inserted into the second insertion space C24. The heater holder C20 may be formed at the heater C50 by insert injection molding.

A through-hole C35 may be formed as the result of the lower wall C32 of the extractor C30 being opened. The through-hole C35 may be open upward and downward. When the extractor C30 is inserted into the heater holder C20, the heater C50 may protrude into the second insertion space C24 through the through-hole C35. When the stick S is inserted into the second insertion space C24, the heater C50 may be inserted into a lower part of the stick S.

The induction coil C15 may surround the first insertion space C14. The induction coil C15 may be wound around the lateral wall C111 of the body pipe C11. The induction coil C15 may cause the heater C50 to generate heat. As another example, the heater C50 may be electrically connected directly to a power source via a terminal formed at the heater holder C20 to receive power and generate heat.

Accordingly, the heater C50 may be easily replaced. The sizes of the insertion spaces C14 and C24 and the heater C50 disposed in the insertion spaces C14 and C24 are very small and it may be difficult to replace the heater C50, but a user may easily replace the heater C50 by separating the heater holder C20 from the aerosol-generating device and placing a new heater holder C20 in the aerosol-generating device.

In addition, the stick S may be easily separated from the heater C50. The user may easily separate the stick S from the heater C50 by separating the extractor C30 and the heater holder C20 from each other. The stick S inserted into the extractor C30 may be separated from the heater C50, whereby the stick may be more easily separated from the extractor C30. The stick S may be separated even in the state in which the extractor C30 and the heater holder C20 are not separated from each other.

In addition, foreign substances generated from the stick S do not remain around the heater C50 and the heater holder C20, and may be extracted through the extractor C30. Accordingly, it may be easy to clean the aerosol-generating device around the heater C50, and convenience of management may be improved. In addition, factors that reduce the performance of the heater C50 may be reduced, the durability of the heater C50 may be improved, and thus, the replacement cycle of the heater may be increased. In addition, factors that change the taste of the stick S may be reduced.

The heater holder C20 may be disposed between the body C10 and the extractor C30. The lateral wall C111 of the body pipe C11 may surround the lateral wall C21 of the heater holder C20 and the lateral wall C31 of the extractor C30. The lower wall C112 of the body pipe C11 may face the lower wall C22 of the heater holder C20. The lower wall C22 of the heater holder C20 may face the lower wall C32 of the extractor C30.

The lower wall C32 of the extractor C30 may be spaced upward apart from the lower wall C22 of the heater holder C20. Air may flow between the extractor C30 and the heater holder C20, may pass through the through-hole C35, and may be supplied to the stick S inserted into the second insertion space C24.

An upper wall C12 of the body C10 may extend outward from the upper end of the body pipe C11 in a horizontal direction. An outer lateral wall C13 of the body C10 may extend downward from an outer end of the upper wall C12 of the body C10. The induction coil C15 may be disposed between the body pipe C11 and the outer lateral wall C13 of the body C10.

The upper case C40 may be detachably coupled to the body C10. The upper case C40 may be coupled to the upper part of the body C10. The upper case C40 may cover the periphery of the first insertion space C14 and the periphery of the upper part of the body C10. The upper case C40 may have the insertion hole C44. The stick S may be inserted into the insertion hole C44. The upper case C40 may include the cap C45 that opens and closes the insertion hole C44. The cap C45 may slide laterally to open and close the insertion hole C44. The heater holder C20 may be disposed between the body C10 and the upper case C40.

The extractor C30 may be coupled to the upper case C40. The upper end of the extractor C30 may be coupled to the upper case C40, and the lower end of the extractor C30 may protrude downward from the upper case C40. The extractor C30 may be coupled to a position corresponding to the insertion hole C44. The insertion hole C44 may be located above the second insertion space C24. The insertion hole C44 may connect the second insertion space C24 to the outside of the aerosol-generating device.

When the upper case C40 is coupled to the body C10, the upper case C40 may form the appearance of the upper part of the aerosol-generating device.

Accordingly, a user may more easily separate the extractor C30 from the body C10. The user may hold the outer part of the upper case C40 and separate the upper case C40 from the body C10, thereby being capable of separating the extractor C30 without inconvenience of gripping the extractor C30 inserted into the second insertion space C24.

The heater holder C20 may include an extension C23. The extension C23 may be formed at the upper end of the heater holder C20. The extension C23 may extend outward in the horizontal direction from the upper end of the pipe C20′. The extension C23 may be referred to as a heater holder extension C23.

The heater holder C20 may include a heater holder wing C26. The heater holder wing C26 may extend downward from both ends of the extension C23.

The extension C23 may have a shape corresponding to the upper wall C12 of the body C10. The heater holder wing C26 may have a shape corresponding to the outer lateral wall C13 of the body C10. When the pipe C20′ is inserted into the first insertion space C14, the extension C23 may be supported or seated on the upper wall C12 of the body C10, and the heater holder wing C26 may face or contact the outer lateral wall C13 of the body C10.

The upper wall C12 of the body C10 may support the extension, and the extension C23 may support the pipe C20′. The pipe C20′ may be suspended from the extension C23 and spaced upward apart from the bottom C112 of the body pipe C11 to form an air gap. The lateral wall C21 of the pipe C20′ and the lateral wall C31 of the extractor C30 may be spaced inward apart from the lateral wall C111 of the body pipe C11 to form an air gap.

The extension C23 may have a shape corresponding to the lower surface of the upper case C40. When the upper case 40 is coupled to the body C10 and the extractor C30 is inserted into the pipe C20′, the extension C23 may come into contact with the lower surface of the upper case C40.

The upper case C40, the extension C23, and the body C10 may each be provided with a coupling member. The coupling members may be provided in the upper case C40, the extension C23, and the body C10 so as to be adjacent to each other in the state in which the upper case C40, the extension C23, and the body C10 are coupled to each other. The heater holder C20 may be removably coupled to the upper case C40 and/or the extractor C30 by the respective coupling members. For example, each coupling member may include at least one of a protrusion and a recess corresponding thereto. However, each coupling member is not limited thereto, and it is sufficient that the heater holder C20 can be removably coupled to the upper case C40 and/or the extractor C30 by the respective coupling members.

Accordingly, the user may selectively couple the heater holder C20 to the body C10 or the extractor C30 with the upper case C40 and/or the extractor C30 separated from the body C10. In addition, the upper case C40 and/or the extractor C30 may be more easily and stably coupled to the body C10.

The lateral wall C21 of the pipe C20′ and the lateral wall C31 of the extractor C30 may be spaced inward apart from the lateral wall C111 of the body pipe C11 to form an air gap. The heater C50 may be surrounded by the extractor C30 and the pipe C20′.

Accordingly, the amount of heat generated by the heater C50 and transferred to the body pipe C11 via the pipe C20′ and the extractor C30 may be reduced, thereby reducing the phenomenon of the aerosol-generating device overheating.

The upper case C40 may be separated from the body C10. The heater holder C20 may be removably coupled to the upper case C40. The heater holder C20 may be separably coupled to the upper case C40 by magnetic attraction, screw coupling, or snap-fit coupling.

When the upper case C40 is separated from the body C10, the heater holder C20 may be separated from the body C10 together with the upper case C40 in a state of being coupled to the upper case C40. In the state in which the upper case C40 to which the heater holder C20 is coupled is separated from the body C10, the heater holder C20 may be separated from the upper case C40.

As another example, the heater holder C20 may be removably coupled to the extractor C30. When the extractor C30 is separated from the body, the heater holder C20 may be separated from the body C10 together with the extractor C30 in a state of being coupled to the extractor C30. In the state in which the extractor C30 to which the heater holder C20 is coupled is separated from the body C10, the heater holder C20 may be separated from the extractor C30.

The heater holder C20 coupled to the upper case C40 may protrude downward from the upper case C40. Accordingly, the heater holder C20 may be easily separated from the upper case C40 and yet be stably coupled to the upper case C40. In addition, the heater C50 may be conveniently replaced.

The heater holder C20 may be removably coupled to the body C10. In the state in which the heater holder C20 is coupled to the body C10, the upper case C40 and/or the extractor C30 may be separated from the body C10 and the heater holder C20. With the upper case C40 and/or the extractor C30 separated from the body C10 and the heater holder C20, the heater holder C20 may be separated from the body C10. The heater holder C20 may be separably connected to the body C10 by magnetic attraction, screw coupling, or snap-fit coupling.

The extension C23 coupled to the body C10 may be exposed upward from the body C10. The heater holder wing C26 coupled to the body C10 may be exposed laterally from the body C10. Accordingly, the heater holder C20 may be easily held.

Accordingly, the heater holder C20 may be easily separated from the body C10 and yet be stably coupled to the body C10. In addition, the heater C50 may be conveniently replaced.

In addition, the stick S may be easily separated from the heater C50. The user may easily separate the stick S from the heater C50 by separating the extractor C30 and the heater holder C20 from each other. The stick S inserted into the extractor C30 may be separated from the heater C50, whereby the stick may be more easily separated from the extractor C30. Referring to FIG. 7, a guide portion C25 may be formed at an inner circumferential surface of an upper end of the pipe C20′. The guide portion C25 may be located between the pipe C20′ and the extension C23. The guide portion C25 may extend obliquely downward.

Accordingly, the guide portion C25 may contact a lower part of the extractor C30 and may guide the extractor C30 to be easily inserted into the heater holder C20.

The lower end of the heater C50 may be inserted into and fixed to the mount C22. The heater C50 may include a heater rod C51. The heater rod C51 may extend upward and downward. The heater rod C51 may have a cylindrical shape. The heater rod C51 may have a hollow C52 open downward. The hollow C52 may extend upward and downward. The hollow C52 in the heater rod C51 may be formed in a cylindrical shape. An upper end of the heater rod C51 may be pointed upward.

The heater rod C51 may be made of a resistive metal.

The heater C50 may include a support body C53. The support body C53 may be disposed under the heater rod C51. The support body C53 may be fixed to the heater rod C51. The support body C53 may support a lower part of the heater rod C51. The support body C53 may fill a lower part of the hollow C52. A lateral surface of the support body C53 may be supported by the mount C22. The support body C53 may have high heat resistance. The support body C53 may be thermally deformed by heat generated by the heater rod C51.

A lower end of the heater rod C51 may be inserted into the support body C53. The support body C53 may be provided with a fitting recess C531 open upward. The fitting recess C531 may extend in the circumferential direction and may have a ring shape. The lower end of the heater rod C51 may be inserted and fitted into the fitting recess C531.

The heater rod C51 may be coupled to the support body C53. A protrusion C511 may protrude outward from an outer circumferential surface of the lower end of the heater rod C51. A plurality of protrusions C511 may be disposed along the outer circumferential surface of the lower end of the heater rod C51 so as to be spaced apart from each other. A protrusion recess may be formed in the outer circumferential surface of the fitting recess C531. The protrusion C511 may be inserted into the protrusion recess.

The support body C53 may have a flange C532 formed on a lateral surface thereof. The flange C532 may extend outward from the lateral surface of the support body C53 along the circumference thereof. The flange C532 may be inserted into the mount C22. The mount C22 may be integrally coupled to the flange C532 as the result of the heater holder C20 being formed at the heater C50 by insert injection molding.

An inner circumferential surface of the mount C22 may have a shape that corresponds to an outer circumferential surface of the flange C532. The inner circumferential surface of the mount C22 and the outer circumferential surface of the flange C532 may be engaged with each other in the circumferential direction. This may prevent the heater C50 from being separated from the heater holder C20 during the process of the stick S being separated from or inserted into the heater C50.

Although not shown in the figures, an aerosol-generating device according to another embodiment of the present disclosure may not include a heater holder C20. The heater C50 may be fixed to the body C10. The heater C50 may be fixed to the lower wall C112 of the body pipe C11 and may extend upward in the first insertion space C14. The upper part of the heater C50 may extend into the second insertion space C24 through the through-hole C35. A hollow may be formed in the heater C50. An electrically conductive track and/or a temperature sensor may be mounted in the hollow of the heater C50. The electrically conductive track may generate heat upon receiving current from the power supply 11, and the heater C50 may be heated by the heat generated by the electrically conductive track.

As another example, the heater C50 may be fixed to the extractor C30. The heater C50 may be fixed to the lower wall C32 of the extractor C30, and may protrude upward in the second insertion space C24. The extractor C30 may be separably inserted into the first insertion space C14. When the extractor C30 is separated from the body C10, the heater C50 may be separated from the body C10 together with the extractor C30.

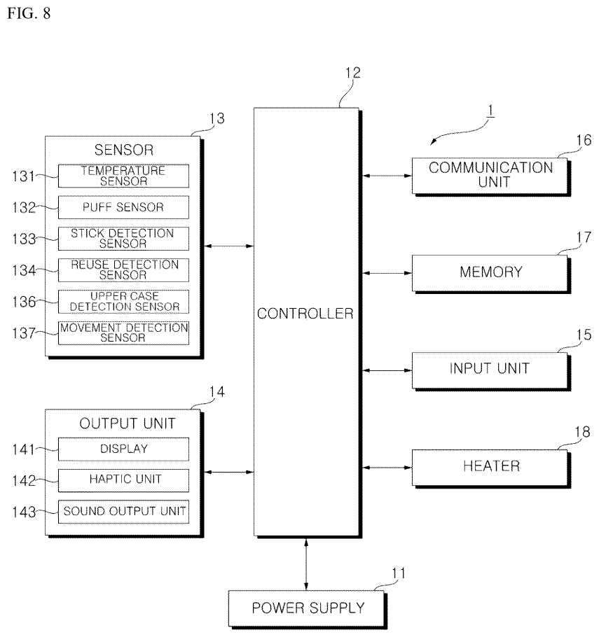

FIG. 8 is a block diagram of an aerosol-generating device 1 according to an embodiment of the present disclosure.

The aerosol-generating device 1 may include a power supply 11, a controller 12, a sensor 13, an output unit 14, an input unit 15, a communication unit 16, a memory 17, and one or more heaters 18 and 24. However, the internal structure of the aerosol-generating device 1 is not limited to that shown in FIG. 8. That is, it is to be understood by those skilled in the art that some of the components shown in FIG. 8 may be omitted or new components may be added depending on the design of the aerosol-generating device 1.

The sensor 13 may detect the state of the aerosol-generating device 1 or the state of the surrounding of the aerosol-generating device 1 and may transmit information about the detected state to the controller 12. Based on the information about the detected state, the controller 12 may control the aerosol-generating device 1 to perform various functions, such as control of operation of the heater 18, smoking restriction, determination as to whether the stick S is inserted, and notification display.

The sensor 13 may include at least one of a temperature sensor 131, a puff sensor 132, a stick detection sensor 133, a reuse detection sensor 134, an upper case detection sensor 136, or a movement detection sensor 137.

The temperature sensor 131 may detect temperature to which the heater 18 is heated. The aerosol-generating device 1 may include a separate temperature sensor configured to detect the temperature of the heater 18, or the heater 18 itself may serve as a temperature sensor.

The temperature sensor 131 may output a signal corresponding to the temperature of the heater 18. For example, the temperature sensor 131 may include a resistive element that changes in resistance value according to a change in temperature of the heater 18. The temperature sensor may be implemented as a thermistor, which is an element characterized in that the resistance thereof changes with temperature. In this case, the temperature sensor 131 may output a signal corresponding to the resistance value of the resistive element as a signal corresponding to the temperature of the heater 18. For example, the temperature sensor 131 may be configured as a sensor configured to detect the resistance value of the heater 18. In this case, the temperature sensor 131 may output a signal corresponding to the resistance value of the heater 18 as a signal corresponding to the temperature of the heater 18.

The temperature sensor 131 may be disposed around the power supply 11 to monitor the temperature of the power supply 11. The temperature sensor 131 may be disposed adjacent to the power supply 11. For example, the temperature sensor 131 may be attached to one surface of the battery, which is the power supply 11. For example, the temperature sensor 131 may be mounted on one surface of a printed circuit board.

The temperature sensor 131 may be disposed in the body 10 to detect the internal temperature of the body 10.

The puff sensor 132 may detect a user puff based on various physical changes in a gasflow path. The puff sensor 132 may output a signal corresponding to a puff. For example, the puff sensor 132 may be a pressure sensor. The puff sensor 132 may output a signal corresponding to the internal pressure of the aerosol-generating device. Here, the internal pressure of the aerosol-generating device 1 may correspond to the pressure of the gasflow path through which gas flows. The puff sensor 132 may be disposed at a position corresponding to the gasflow path through which gas flows in the aerosol-generating device 1.

The stick detection sensor 133 may detect insertion and/or removal of the stick S. The stick detection sensor 133 may detect a signal change caused by insertion and/or removal of the stick S. The stick detection sensor 133 may be mounted around the insertion space. The stick detection sensor 133 may detect insertion and/or removal of the stick S according to a change in dielectric constant in the insertion space. For example, the stick detection sensor 133 may be an inductive sensor and/or a capacitance sensor.

The inductive sensor may include at least one coil. The coil of the inductive sensor may be disposed adjacent to the insertion space. For example, if a magnetic field changes around a coil through which current flows, the characteristics of the current flowing through the coil may change according to Faraday's law of electromagnetic induction. Here, the characteristics of the current flowing through the coil may include a frequency of alternating current, a current value, a voltage value, an inductance value, an impedance value, and the like.

The inductive sensor may output a signal corresponding to the characteristics of the current flowing through the coil. For example, the inductive sensor may output a signal corresponding to the inductance value of the coil.

The capacitance sensor may include a conductive body. The conductive body of the capacitance sensor may be disposed adjacent to the insertion space. The capacitance sensor may output a signal corresponding to the electromagnetic characteristics of the surroundings, for example, the capacitance around the conductive body. For example, if the stick S including a metallic wrapper is inserted into the insertion space, the electromagnetic characteristics around the conductive body may change due to the wrapper of the stick S.

The reuse detection sensor 134 may detect whether the stick S is being reused. The reuse detection sensor 134 may be a color sensor. The color sensor may detect the color of the stick S. The color sensor may detect the color of a portion of the wrapper surrounding the outer side of the stick S. The color sensor may detect, based on light reflected from an object, a value for the optical characteristic corresponding to the color of the object. For example, the optical characteristic may be the wavelength of light. The color sensor may be implemented as a component integrated with a proximity sensor or may be implemented as a component provided separately from a proximity sensor.

At least a portion of the wrapper constituting the stick S may change in color due to an aerosol. The reuse detection sensor 134 may be disposed at a position corresponding to a position at which at least a portion of the wrapper, which changes in color due to an aerosol, is disposed when the stick S is inserted into the insertion space. For example, before the stick S is used by the user, the color of at least a portion of the wrapper may be a first color. In this case, while the aerosol generated by the aerosol-generating device 1 passes through the stick S, at least a portion of the wrapper may become wet due to the aerosol, and accordingly, the color of at least a portion of the wrapper may change to a second color. After changing from the first color to the second color, the color of at least a portion of the wrapper may be maintained in the second color.

The upper case detection sensor 136 may detect mounting and/or removal of the upper case. When the upper case is separated from the body 10, the portion of the body 10 that have been covered by the upper case may be exposed to the outside. The upper case detection sensor 136 may be implemented as a contact sensor, a Hall sensor (or Hall IC), an optical sensor, etc.

The movement detection sensor 137 may detect movement of the aerosol-generating device. The movement detection sensor 137 may be implemented as at least one of an acceleration sensor or a gyro sensor.

In addition to the sensors 131 to 137 described above, the sensor 13 may further include at least one of a humidity sensor, a barometric pressure sensor, a magnetic sensor, a position sensor (GPS), or a proximity sensor. The functions of the sensors could be intuitively deduced by those skilled in the art from the names thereof, and thus detailed descriptions thereof will be omitted.

The output unit 14 may output information about the state of the aerosol-generating device 1 and may provide the information to the user. The output unit 14 may include at least one of a display 141, a haptic unit 142, or a sound output unit 143. However, the disclosure is not limited thereto. If the display 141 and a touchpad form a touchscreen together in a layered structure, the display 141 may be used as not only an output device but also an input device.

The display 141 may visually provide information about the aerosol-generating device 1 to the user. For example, the information about the aerosol-generating device 1 may include various pieces of information, such as a charging/discharging state of the power supply 11 of the aerosol-generating device 1, a preheating state of the heater 18, an insertion/removal state of the stick S, a mounting/removal state of the ca [, and a use restriction state of the aerosol-generating device 1 (e.g., detection of an abnormal article), and the display 141 may output the information to the outside. For example, the display 141 may be in the form of a light-emitting diode (LED) device. For example, the display 141 may be a liquid crystal display panel (LCD), an organic light-emitting display panel (OLED), or the like.

The haptic unit 142 may convert an electrical signal into mechanical stimulation or electrical stimulation to haptically provide the information about the aerosol-generating device 1 to the user. For example, if initial power is supplied to the heater 18 for a predetermined amount of time, the haptic unit 142 may generate vibration corresponding to completion of initial preheating. The haptic unit 142 may include a vibration motor, a piezoelectric element, or an electrical stimulation device.

The sound output unit 143 may audibly provide information about the aerosol-generating device 1 to the user. For example, the sound output unit 143 may convert an electrical signal into an acoustic signal and may output the acoustic signal to the outside.

The power supply 11 may supply power used for operation of the aerosol-generating device 1. The power supply 11 may supply power so that the heater 18 is heated. In addition, the power supply 11 may supply power necessary for operation of the other components provided in the aerosol-generating device 1, such as the sensor 13, the output unit 14, the input unit 15, the communication unit 16, and the memory 17. The power supply 11 may be a rechargeable battery or a disposable battery. For example, the power supply 11 may be a lithium polymer (LiPoly) battery. However, the disclosure is not limited thereto.

Although not shown in FIG. 8, the aerosol-generating device 1 may further include a power supply protection circuit. The power supply protection circuit may be electrically connected to the power supply 11 and may include a switching element.

The power supply protection circuit may block an electric path to the power supply 11 according to a predetermined condition. For example, the power supply protection circuit may block the electric path to the power supply 11 when the voltage level of the power supply 11 is equal to or higher than a first voltage corresponding to overcharge. For example, the power supply protection circuit may block the electric path to the power supply 11 when the voltage level of the power supply 11 is lower than a second voltage corresponding to overdischarge.

The heater 18 may receive power from the power supply 11 to heat the medium or the aerosol-generating substance in the stick S. Although not shown in FIG. 8, the aerosol-generating device 1 may further include a power conversion circuit (e.g., DC-to-DC converter) configured to convert the power of the power supply 11 and supply the converted power to the heater 18. In addition, if the aerosol-generating device 1 generates an aerosol in an induction heating way, the aerosol-generating device 1 may further include a DC-to-AC converter configured to convert direct current power of the power supply 11 into alternating current power.

The controller 12, the sensor 13, the output unit 14, the input unit 15, the communication unit 16, and the memory 17 may perform functions using power received from the power supply 11. Although not shown in FIG. 8, the aerosol-generating device may further include a power conversion circuit configured to convert the power of the power supply 11 and supply the converted power to the respective components, for example, a low dropout (LDO) circuit or a voltage regulator circuit. In addition, although not shown in FIG. 8, a noise filter may be provided between the power supply 11 and the heater 18. The noise filter may be a low-pass filter. The low-pass filter may include at least one inductor and a capacitor. The cutoff frequency of the low-pass filter may correspond to the frequency of a high-frequency switching current applied from the power supply 11 to the heater 18. The low-pass filter may prevent high-frequency noise components from being applied to the sensor 13, for example, the stick detection sensor 133.

In an embodiment, the heater 18 may be formed of any suitable electrically resistive material. For example, the suitable electrically resistive material may be a metal or a metal alloy including titanium, zirconium, tantalum, platinum, nickel, cobalt, chromium, hafnium, niobium, molybdenum, tungsten, tin, gallium, manganese, iron, copper, stainless steel, or nichrome. However, the disclosure is not limited thereto. In addition, the heater 18 may be implemented as a metal wire, a metal plate on which an electrically conductive track is disposed, or a ceramic heating element. However, the disclosure is not limited thereto.

In another embodiment, the heater 18 may be an induction heater. For example, the heater 18 may include a susceptor configured to generate heat through a magnetic field applied by a coil, thereby heating the aerosol-generating substance.

The input unit 15 may receive information input from the user or may output information to the user. For example, the input unit 15 may be a touch panel. The touch panel may include at least one touch sensor configured to detect touch. For example, the touch sensor may include a capacitive touch sensor, a resistive touch sensor, a surface acoustic wave touch sensor, an infrared touch sensor, etc. However, the disclosure is not limited thereto.

The display 141 and the touch panel may be implemented as an integrated panel. For example, the touch panel may be inserted into the display 141 (on-cell type touch panel or in-cell type touch panel). For example, the touch panel may be added onto the display 141 (add-on type touch panel).

Meanwhile, the input unit 15 may include a button, a keypad, a dome switch, a jog wheel, a jog switch, etc. However, the disclosure is not limited thereto.

The memory 17 may be hardware storing various pieces of data processed in the aerosol-generating device 1. The memory 17 may store data processed and to be processed by the controller 12. The memory 17 may include at least one type of storage medium among a flash memory type memory, a hard disk type memory, a multimedia card micro type memory, a card type memory (e.g., SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc. The memory 17 may store data on an operation time of the aerosol-generating device 1, the maximum number of puffs, the current number of puffs, at least one temperature profile, and the user's smoking pattern.

The communication unit 16 may include at least one component for communication with other electronic devices. For example, the communication unit 16 may include at least one of a short-range communication unit or a wireless communication unit.

The short-range communication unit may include a Bluetooth communication unit, a Bluetooth low energy (BLE) communication unit, a near-field communication unit, a WLAN (Wi-Fi) communication unit, a Zigbee communication unit, an infrared data association (IrDA) communication unit, a Wi-Fi direct (WFD) communication unit, an ultra-wideband (UWB) communication unit, an Ant+communication unit, etc. However, the disclosure is not limited thereto.

The wireless communication unit may include a cellular network communication unit, an Internet communication unit, a computer network (e.g., LAN or WAN) communication unit, etc. However, the disclosure is not limited thereto.

Although not shown in FIG. 8, the aerosol-generating device 1 may further include a connection interface such as a universal serial bus (USB) interface, and may be connected to other external devices through the connection interface such as a USB interface to transmit and receive information or charge the power supply 11.

The controller 12 may control overall operation of the aerosol-generating device 1. In an embodiment, the controller 1 may include at least one processor. The processor may be implemented as an array of a plurality of logic gates or may be implemented as a combination of a general-purpose microprocessor and a memory in which a program executable in the microprocessor is stored. Also, it will be understood by those skilled in the art that the processor can be implemented in other forms of hardware.

The controller 12 may control the supply of power from the power supply 11 to the heater 18 to control the temperature of the heater 18. The controller 12 may control the temperature of the heater 18 based on the temperature of the heater 18 detected by the temperature sensor 131. The controller 12 may control the power supplied to the heater 18 based on the temperature of the heater 18. For example, the controller 12 may determine a target temperature of the heater 18 based on the temperature profile stored in the memory 17.

The aerosol-generating device 1 may include a power supply circuit (not shown) electrically connected to the power supply 11 between the power supply 11 and the heater 18. The power supply circuit may be electrically connected to the heater 18 or the induction coil 181. The power supply circuit may include at least one switching element. The switching element may be implemented as a bipolar junction transistor (BJT), a field effect transistor (FET), or the like. The controller 12 may control the power supply circuit.

The controller 12 may control switching of the switching element of the power supply circuit to control the supply of power. The power supply circuit may be an inverter configured to convert direct current power output from the power supply 11 into alternating current power. For example, the inverter may be composed of a full-bridge circuit or a half-bridge circuit including a plurality of switching elements.

The controller 12 may turn on the switching element so that power is supplied from the power supply 11 to the heater 18. The controller 12 may turn off the switching element so that the supply of power to the heater 18 is interrupted. The controller 12 may control the frequency and/or the duty ratio of the current pulse input to the switching element to control the current supplied from the power supply 11.

The controller 12 may control switching of the switching element of the power supply circuit to control the voltage output from the power supply 11. The power conversion circuit may convert the voltage output from the power supply 11. For example, the power conversion circuit may include a buck-converter configured to step down the voltage output from the power supply 11. For example, the power conversion circuit may be implemented as a buck-boost converter, a Zener diode, or the like.

The controller 12 may control on/off operation of the switching element included in the power conversion circuit to control the level of the voltage output from the power conversion circuit. If the switching element is maintained in an on state, the level of the voltage output from the power conversion circuit may correspond to the level of the voltage output from the power supply 11. The duty ratio for the on/off operation of the switching element may correspond to a ratio of the voltage output from the power conversion circuit to the voltage output from the power supply 11. As the duty ratio for the on/off operation of the switching element decreases, the level of the voltage output from the power conversion circuit may decrease. The heater 18 may be heated based on the voltage output from the power conversion circuit.

The controller 12 may control the supply of power to the heater 18 using at least one of a pulse width modulation (PWM) scheme or a proportional-integral-differential (PID) scheme.

For example, the controller 12 may perform control using the PWM scheme such that a current pulse having a predetermined frequency and a predetermined duty ratio is supplied to the heater 18. The controller 12 may control the frequency and the duty ratio of the current pulse to control the power supplied to the heater 18.

For example, the controller 12 may determine, based on the temperature profile, a target temperature to be controlled. The controller 12 may control the power supplied to the heater 18 using the PID scheme, which is a feedback control scheme using a difference value between the temperature of the heater 18 and the target temperature, a value obtained by integrating the difference value with respect to time, and a value obtained by differentiating the difference value with respect to time.

The controller 12 may prevent the heater 18 from overheating. For example, the controller 12 may control operation of the power conversion circuit such that the supply of power to the heater 18 is interrupted when the temperature of the heater 18 exceeds a predetermined limit temperature. For example, the controller 12 may reduce the amount of power supplied to the heater 18 by a predetermined ratio when the temperature of the heater 18 exceeds a predetermined limit temperature.

The controller 12 may control charging/discharging of the power supply 11. The controller 12 may check the temperature of the power supply 11 based on an output signal from the temperature sensor 131.

If a power line is connected to a battery terminal of the aerosol-generating device 1, the controller 12 may determine whether the temperature of the power supply 11 is equal to or higher than a first limit temperature, which is a reference temperature at which charging of the power supply 11 is interrupted. When the temperature of the power supply 11 is lower than the first limit temperature, the controller 12 may perform control such that the power supply 11 is charged based on a predetermined charging current. When the temperature of the power supply 11 is equal to or higher than the first limit temperature, the controller 12 may interrupt charging of the power supply 11.

When the aerosol-generating device 1 is in an on state, the controller 12 may determine whether the temperature of the power supply 11 is equal to or higher than a second limit temperature, which is a reference temperature at which discharging of the power supply 11 is interrupted. When the temperature of the power supply 11 is lower than the second limit temperature, the controller 12 may perform control such that the power stored in the power supply 11 is used. When the temperature of the power supply 11 is equal to or higher than the second limit temperature, the controller 12 may interrupt use of the power stored in the power supply 11.

The controller 12 may calculate or determine the remaining amount of power stored in the power supply 11. For example, the controller 12 may calculate or determine the remaining capacity of the power supply 11 based on a voltage and/or current detection value of the power supply 11.

The controller 12 may determine whether the stick S is inserted into the insertion space using the stick detection sensor 133. The controller 12 may determine that the stick S is inserted based on an output signal from the stick detection sensor 133. Upon determining that the stick S is inserted into the insertion space, the controller 12 may perform control such that power is supplied to the heater 18. For example, the controller 12 may supply power to the heater 18 based on the temperature profile stored in the memory 17.

The controller 12 may determine whether the stick S is removed from the insertion space. For example, the controller 12 may determine whether the stick S is removed from the insertion space using the stick detection sensor 133. For example, the controller 12 may determine that the stick S is removed from the insertion space when the temperature of the heater 18 is equal to or higher than a limit temperature or when the temperature change slope of the heater 18 is equal to or greater than a predetermined slope. Upon determining that the stick S is removed from the insertion space, the controller 12 may interrupt the supply of power to the heater 18.

The controller 12 may control a power supply time and/or the amount of power supplied to the heater 18 depending on the state of the stick S detected by the sensor 13. The controller 12 may check, based on a look-up table, a level range within which the level of a signal from the capacitance sensor is included. The controller 12 may determine the amount of moisture in the stick S based on the checked level range.

When the stick S is in a highly humid state, the controller 12 may control a time during which power is supplied to the heater 18 to increase a preheating time of the stick S compared to when the stick S is in a normal state.

The controller 12 may determine whether the stick S inserted into the insertion space is a reused stick using the reuse detection sensor 134. For example, the controller 12 may compare a sensing value of a signal from the reuse detection sensor with a first reference range within which the first color is included, and may determine that the stick S is not a reused stick when the sensing value is within the first reference range. For example, the controller 12 may compare a sensing value of a signal from the reuse detection sensor with a second reference range within which the second color is included, and may determine that the stick S is a reused stick when the sensing value is within the second reference range. Upon determining that the stick S is a reused stick, the controller 12 may interrupt the supply of power to the heater 18.

The controller 12 may determine whether the cartridge 19 is coupled and/or removed using the cartridge detection sensor 135. For example, the controller 12 may determine whether the cartridge 19 is coupled and/or removed based on a sensing value of a signal from the cartridge detection sensor.

The controller 12 may determine whether the aerosol-generating substance in the cartridge 19 is exhausted. For example, the controller 12 may apply power to preheat the heater 18, and may determine whether the temperature of the cartridge heater 24 exceeds a limit temperature in a preheating section. When the temperature of the cartridge heater 24 exceeds the limit temperature, the controller 12 may determine that the aerosol-generating substance in the cartridge 19 has been exhausted. Upon determining that the aerosol-generating substance in the cartridge 19 has been exhausted, the controller 12 may interrupt the supply of power to the heater 18.

The controller 12 may determine whether use of the cartridge 19 is possible. For example, upon determining, based on the data stored in the memory 17, that the current number of puffs is equal to or greater than the maximum number of puffs set for the cartridge 19, the controller 12 may determine that use of the cartridge 19 is impossible. For example, when a total time period during which the cartridge heater 24 is heated is equal to or longer than a predetermined maximum time period or when the total amount of power supplied to the cartridge heater 24 is equal to or greater than a predetermined maximum amount of power, the controller 12 may determine that use of the cartridge 19 is impossible.

The controller 12 may make a determination as to a user puff using the puff sensor 132. For example, the controller 12 may determine, based on a sensing value of a signal from the puff sensor, whether a puff occurs. For example, the controller 12 may determine the intensity of a puff based on a sensing value of a signal from the puff sensor 132. When the number of puffs reaches a predetermined maximum number of puffs or when no puff is detected for a predetermined time period or longer, the controller 12 may interrupt the supply of power to the heater 18.

The controller 12 may determine whether the upper case is coupled and/or removed using the upper case detection sensor 136. For example, the controller 12 may determine, based on a sensing value of a signal from the upper case detection sensor, whether the upper case is coupled and/or removed.

The controller 12 may control the output unit 14 based on a result of detection by the sensor 13. For example, when the number of puffs counted through the puff sensor 132 reaches a predetermined number, the controller 12 may notify the user that operation of the aerosol-generating device 1 will end soon through at least one of the display 141, the haptic unit 142, or the sound output unit 143. For example, upon determining that the stick S is not present in the insertion space, the controller 12 may notify the user of the determination result through the output unit 14. For example, upon determining that the upper case has not been mounted, the controller 12 may notify the user of the determination result through the output unit 14. For example, the controller 12 may transmit information about the temperature of the heater 18 to the user through the output unit 14.

Upon determining that a predetermined event has occurred, the controller 12 may store a history of the corresponding event in the memory 17 and may update the history. The event may include events performed in the aerosol-generating device 1, such as detection of insertion of the stick S, commencement of heating of the stick S, detection of puff, termination of puff, detection of overheating of the heater 18, detection of application of overvoltage to the heater 18, termination of heating of the stick S, on/off operation of the aerosol-generating device 1, commencement of charging of the power supply 11, detection of overcharging of the power supply 11, and termination of charging of the power supply 11. The history of the event may include the occurrence date and time of the event and log data corresponding to the event. For example, when the predetermined event is detection of insertion of the stick S, the log data corresponding to the event may include data on a value detected by the stick detection sensor 133. For example, when the predetermined event is detection of overheating of the heater 18, the log data corresponding to the event may include data on the temperature of the heater 18, the voltage applied to the heater 18, and the current flowing through the heater 18.

The controller 12 may perform control for formation of a communication link with an external device such as a user's mobile terminal. Upon receiving data on authentication from an external device via the communication link, the controller 12 may release restriction on use of at least one function of the aerosol-generating device 1. Here, the data on authentication may include data indicating completion of user authentication for the user corresponding to the external device. The user may perform user authentication through the external device. The external device may determine, based on the user's birthday or an identification number indicating the user, whether the user data is valid, and may receive data on the authority for use of the aerosol-generating device 1 from an external server. The external device may transmit data indicating completion of user authentication to the aerosol-generating device 1 based on the data on the use authority. When the user authentication is completed, the controller 12 may release restriction on use of at least one function of the aerosol-generating device 1. For example, when the user authentication is completed, the controller 12 may release restriction on use of a heating function for supplying power to the heater 18.

The controller 12 may transmit data on the state of the aerosol-generating device 1 to the external device through the communication link established with the external device. Based on the received state data, the external device may output the remaining capacity of the power supply 11 or the operation mode of the aerosol-generating device 1 through a display of the external device.

The external device may transmit a location search request to the aerosol-generating device 1 based on an input for commencement of search for the location of the aerosol-generating device 1. Upon receiving the location search request from the external device, the controller 12 may perform control, based on the received location search request, such that at least one of the output devices performs operation corresponding to location search. For example, the haptic unit 142 may generate vibration in response to the location search request. For example, the display 141 may output objects corresponding to location search and termination of search in response to the location search request.

Upon receiving firmware data from the external device, the controller 12 may perform control such that the firmware is updated. The external device may check the current version of the firmware of the aerosol-generating device 1 and may determine whether there is a new version of firmware. Upon receiving an input requesting firmware download, the external device may receive new version of firmware data and may transmit the new version of firmware data to the aerosol-generating device 1. Upon receiving the new version of firmware data, the controller 12 may perform control such that the firmware of the aerosol-generating device 1 is updated.

The controller 12 may transmit data on a value detected by the at least one sensor 13 to an external server (not shown) through the communication unit 16, and may receive, from the server, and store a learning model generated by learning the detected value through machine learning such as deep learning. The controller 12 may perform operation of determining the user's puff pattern and operation of generating the temperature profile using the learning model received from the server. The controller 12 may store data on the value detected by the at least one sensor 13 and data for training an artificial neural network (ANN) in the memory 17. For example, the memory 17 may store a database for each of the components provided in the aerosol-generating device 1 and weights and biases constituting the structure of the artificial neural network (ANN) in order to train the artificial neural network (ANN). The controller 12 may learn data on the value detected by the at least one sensor 13, the user's puff pattern, and the temperature profile, which are stored in the memory 17, and may generate at least one learning model used to determine the user's puff pattern and to generate the temperature profile.

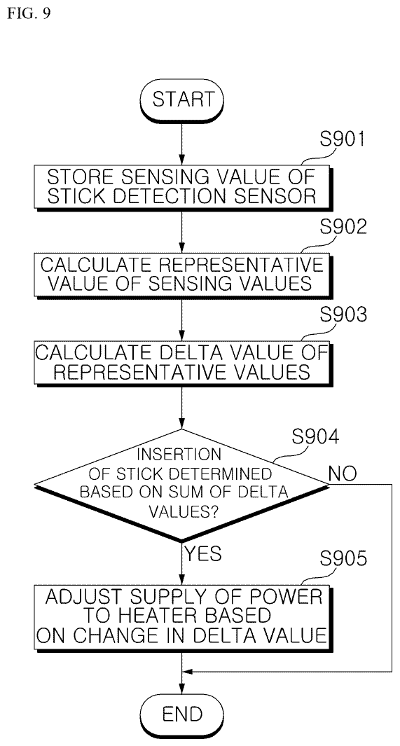

FIG. 9 is a flowchart showing a method of operating an aerosol-generating device according to an embodiment of the present disclosure. In the present disclosure, a description will be given based on the case where the stick S is inserted into the insertion space, the present disclosure may also apply to the case where the stick S is removed from the insertion space.

Referring to FIG. 9, in operation S901, the aerosol-generating device 1 may store a sensing value output from the stick detection sensor 133 in the memory 17 according to a predetermined cycle. According to an embodiment, the sensing value of the stick detection sensor 133 may correspond to the capacitance of the insertion space. For example, when the stick S is inserted into the insertion space, the capacitance of the insertion space may increase. At this time, as the charging voltage to the stick detection sensor 133 increases, the sensing value of the signal output from the stick detection sensor 133 may decrease. In the present disclosure, a description will be given based on the case where the level of the sensing value of the signal output from the stick detection sensor 133 is reduced when the stick S is inserted into the insertion space.

Meanwhile, the predetermined cycle may be set in various ways. For example, the predetermined cycle may be set to any one of a cycle of 0.1 seconds to a cycle of 0.7 seconds.

According to an embodiment, the cycle at which the sensing value output from the stick detection sensor 133 is stored in the memory 17 may be changed depending on the state of the stick S. For example, the aerosol-generating device 1 may store the sensing value of the stick detection sensor 133 in the memory according to a first cycle in the state in which the stick S is removed. For example, the aerosol-generating device 1 may store the sensing value of the stick detection sensor 133 in the memory according to a second cycle in the state in which the stick S is inserted. At this time, the first cycle may be shorter than the second cycle. For example, the first cycle may be 0.6 seconds, and the second cycle may be 0.5 seconds. As a result, removal of the stick may be determined more quickly than insertion of the stick.

In operation S902, the aerosol-generating device 1 may calculate a representative value of a plurality of consecutive sensing values stored in the memory 17. Here, the representative value includes an average value and a median value. In the present disclosure, a description will be given based on the case where the representative value is the average value by way of example. For example, the aerosol-generating device 1 may calculate the average value of a first sensing value stored in the memory 17 and a second sensing value stored immediately after the first sensing value is stored as the representative value of the two sensing values.

In operation S903, the aerosol-generating device 1 may calculate a delta value, which is the difference between two consecutive representative values. For example, the aerosol-generating device 1 may calculate a delta value, which is the difference between a first representative value and a second representative value calculated immediately after the first representative value is calculated.

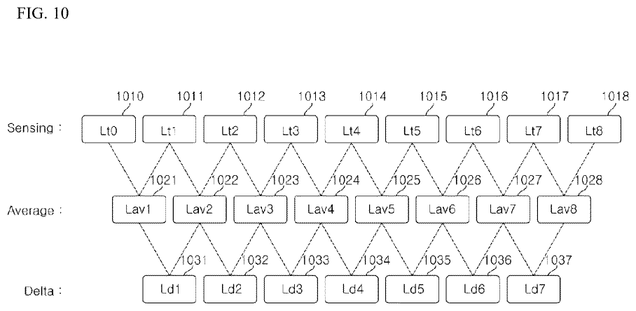

Referring to FIG. 10, sensing values output from the stick detection sensor 133 may be stored in a plurality of sensing buffers 1010 to 1018 of the memory 17 according to a predetermined cycle. A first sensing value Lt1 to an eighth sensing value Lt8 may be sequentially stored in the plurality of sensing buffers 1010 to 1018.

The representative value of the sensing values stored in the plurality of sensing buffers 1010 to 1018 may be stored in a plurality of average buffers 1021 to 1028 of the memory 17. A first average value Lav1, which is the representative value of a sensing value Lt0 stored immediately before the first sensing value Lt1 is stored and the first sensing value, may be stored in the first average buffer 1021, and a second average value Lav2, which is the representative value of the first sensing value Lt1 and the second sensing value Lt2, may be stored in the second average buffer 1022. That is, the first average value Lav1 to an eighth average value Lav8 may be sequentially stored in the plurality of average buffers 1021 to 1028.

A delta value, which is the difference between the representative values stored in the plurality of average buffers 1021 to 1028, may be stored in a plurality of delta buffers 1031 to 1037 of the memory 17. A first delta value Ld1, which is the result of subtracting the second average value Lav2 from the first average value Lav1, may be stored in the first delta buffer 1031. The first delta value Ld1 to a seventh delta value Ld7 may be sequentially stored in the plurality of delta buffers 1031 to 1037.

Referring back to FIG. 9, in operation S904, the aerosol-generating device 1 may determine whether the stick S is inserted into the insertion space based on the sum of a predetermined number of consecutive delta values. At this time, the aerosol-generating device 1 may determine whether the stick S is inserted into the insertion space based on the sum of a predetermined number of recently calculated delta values. For example, the aerosol-generating device 1 may determine that the stick S is inserted into the insertion space if the sum of the delta values is greater than or equal to a predetermined threshold. Meanwhile, as the predetermined number increases, the accuracy of determination on the stick S may be improved. As the predetermined number decreases, the time required for determination on the stick S may be reduced.

According to an embodiment, the aerosol-generating device 1 may calculate the sum of the delta values if the magnitude of the delta value is greater than or equal to a predetermined minimum value. For example, the aerosol-generating device 1 may calculate the sum of a predetermined number of consecutively calculated delta values, including the first delta value Ld1, if the magnitude of the first delta value Ld1 is greater than or equal to the minimum value.

When the stick S is inserted, the aerosol-generating device 1 may be powered on. When the aerosol-generating device 1 is powered on, a preliminary operation for supplying power to the heater 18 may be performed. For example, the aerosol-generating device 1 may supply power to the temperature sensor 131. For example, the aerosol-generating device 1 may drive the power conversion circuit that converts power of the power supply 11 and supplies the same to the heater 18. Meanwhile, in operation S905, the aerosol-generating device 1 may supply power to the heater 18 in response to the insertion of the stick S after the preliminary operation for supplying power to the heater 18 is completed.

In operation S905, the aerosol-generating device 1 may adjust the supply of power to the heater 18 based on a change in the delta value when the stick S is inserted. If the stick S is inserted while there is still an aerosol in the insertion space, the aerosol remaining in the insertion space may be absorbed by the stick S. At this time, the capacitance of the insertion space may change as the aerosol remaining in the insertion space is absorbed by the stick S.

The aerosol-generating device 1 may adjust the supply of power to the heater 18 based on a first temperature profile if the signs of the delta values are all the same. Here, the first temperature profile may be a temperature profile corresponding to the case where the stick S is inserted into the insertion space in the state in which there is no aerosol in the insertion space. Meanwhile, the aerosol-generating device 1 may adjust the supply of power to the heater 18 based on a second temperature profile if the sign of at least one of the delta values is different from the sign of the rest. Here, the second temperature profile may be a temperature profile corresponding to the case where the stick S is inserted in the state in which there is still an aerosol in the insertion space.

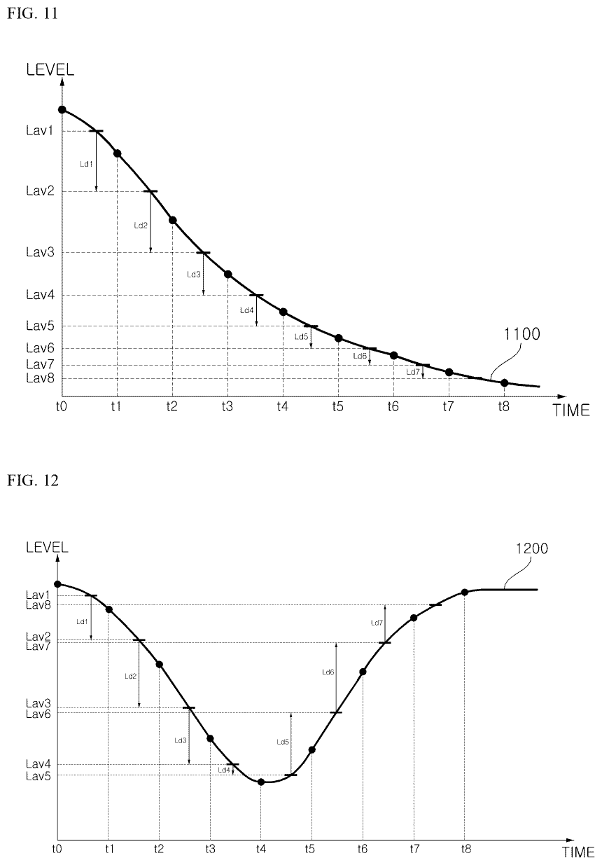

Referring to FIG. 11, when the stick S is inserted into the insertion space, a sensing value 1100 output from the stick detection sensor 133 may continuously decrease as the capacitance of the insertion space increases.

While the stick S is located in the insertion space, representative values Lav1 to Lav8 of a plurality of consecutive sensing values and delta values Ld1 to Ld7, which are the differences between the representative values Lav1 to Lav8, may be calculated. If the sum of a predetermined number of seven consecutive delta values Ld1 to Ld7 is greater than or equal to a predetermined threshold, the aerosol-generating device 1 may determine that the stick S is inserted in the insertion space.

Meanwhile, since the signs of the delta values Ld1 to Ld7 are all the same, the aerosol-generating device 1 may adjust the supply of power to the heater 18 based on the first temperature profile.

Referring to FIG. 12, a sensing value 1200 output from the stick detection sensor 133 may decrease as the capacitance of the insertion space increases while a part of the stick S is located in the insertion space. Meanwhile, as the capacitance of the insertion space decreases while the stick S is removed from the insertion space again, the sensing value 1200 output from the stick detection sensor 133 may increase again.

While the stick S is located in the insertion space, representative values Lav1 to Lav8 of a plurality of consecutive sensing values and delta values Ld1 to Ld7, which are the differences between the representative values Lav1 to Lav8, may be calculated. If the sum of a predetermined number of seven consecutive delta values Ld1 to Ld7 is less than the predetermined threshold, the aerosol-generating device 1 may determine that the stick S has not been inserted in the insertion space.

Meanwhile, if the predetermined number is four, the sum of four consecutive delta values Ld1 to Ld4 may be greater than or equal to the predetermined threshold. At this time, the aerosol-generating device 1 may determine that the stick S is inserted in the insertion space. In addition, if the sum of four subsequent consecutive delta values Ld4 to Ld7 is less than the predetermined threshold corresponding to the removal of the stick S, the aerosol-generating device 1 may determine that the stick S is removed from the insertion space. In this case, the aerosol-generating device 1 may be powered on and then powered off again.

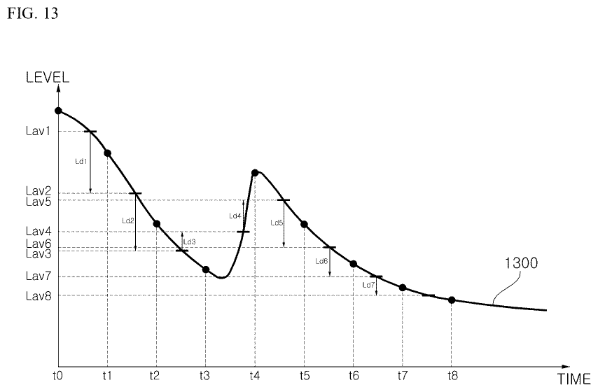

Referring to FIG. 13, when the stick S is inserted into the insertion space, a sensing value 1300 output from the stick detection sensor 133 may continuously decrease as the capacitance of the insertion space increases.

While the stick S is located in the insertion space, representative values Lav1 to Lav8 of a plurality of consecutive sensing values and delta values Ld1 to Ld7, which are the differences between the representative values Lav1 to Lav8, may be calculated. If the sum of a predetermined number of seven consecutive delta values Ld1 to Ld7 is greater than or equal to the predetermined threshold, the aerosol-generating device 1 may determine that the stick S is inserted in the insertion space.

Meanwhile, since the sign of some Ld3 and Ld4 of the delta values Ld1 to Ld7 is different from the sign of the rest, the aerosol-generating device 1 may adjust the supply of power to the heater 18 based on the second temperature profile.

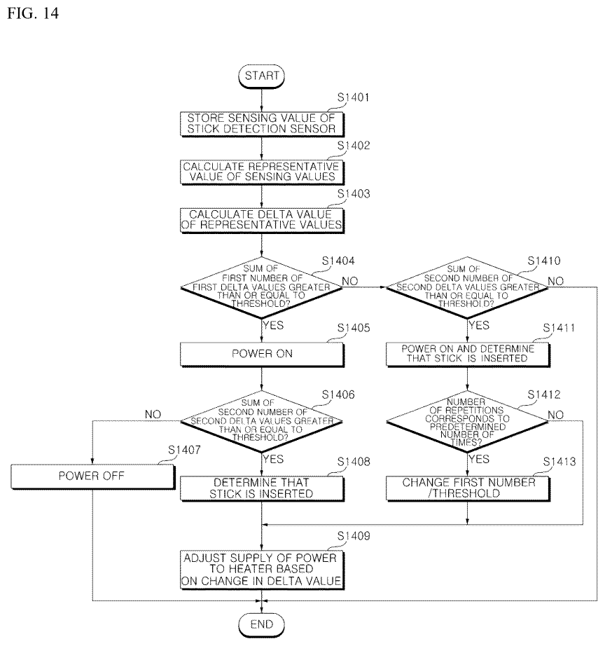

FIG. 14 is a flowchart showing a method of operating an aerosol-generating device according to another embodiment of the present disclosure. A detailed description of the same configuration as the above will be omitted.

Referring to FIG. 14, in operation $1401, the aerosol-generating device 1 may store a sensing value output from the stick detection sensor 133 in the memory 17 according to a predetermined cycle.

In operation S1402, the aerosol-generating device 1 may calculate the representative value of a plurality of consecutive sensing values stored in the memory 17.

In operation S1403, the aerosol-generating device 1 may calculate a delta value, which is the difference between two consecutive representative values.

In operation S1404, the aerosol-generating device 1 may determine whether the sum of a first number of consecutive delta values is greater than or equal to a predetermined threshold. For example, the aerosol-generating device 1 may determine whether the sum of three consecutive delta values is greater than or equal to the predetermined threshold.

In operation S1405, if the sum of the first number of consecutive delta values is greater than or equal to the predetermined threshold, the aerosol-generating device 1 may be powered on.

In operation S1406, the aerosol-generating device 1 may determine whether the sum of a second number of consecutive delta values is greater than or equal to the predetermined threshold. At this time, the second number may be greater than the first number. For example, the aerosol-generating device 1 may determine whether the sum of seven consecutive delta values is greater than or equal to the predetermined threshold.

Some of the second number of consecutive delta values may be the first number of consecutive delta values. For example, the aerosol-generating device 1 may calculate the sum of the second number of consecutive delta values by calculating the sum of three consecutive delta values and additionally summing four delta values.

In operation S1407, if the sum of the second number of consecutive delta values is less than the predetermined threshold, the aerosol-generating device 1 may be powered off.

In operation S1408, if the sum of the second number of consecutive delta values is greater than or equal to the predetermined threshold, the aerosol-generating device 1 may determine that the stick S is inserted into the insertion space. At this time, since the aerosol-generating device 1 is on, power may be quickly supplied to the heater 18.

In operation S1409, when the stick S is inserted, the aerosol-generating device 1 may adjust the supply of power to the heater 18 based on a change in the delta value.

Meanwhile, in operation S1410, if the sum of the first number of consecutive delta values is less than the predetermined threshold, the aerosol-generating device 1 may determine whether the sum of the second number of consecutive delta values is greater than or equal to the predetermined threshold.

In operation S1411, if the sum of the second number of consecutive delta values is greater than or equal to the predetermined threshold while the sum of the first number of consecutive delta values is less than the predetermined threshold, the aerosol generation apparatus 1 may be powered on. In addition, the aerosol-generating device 1 may determine that the stick S is inserted into the insertion space.

If the sum of the second number of consecutive delta values is greater than or equal to the predetermined threshold while the sum of the first number of consecutive delta values is less than the predetermined threshold, the aerosol-generating device 1 may update the number of repetitions. For example, the aerosol-generating device 1 may increase the number of repetitions by one. Meanwhile, the aerosol-generating device 1 may reset the number of repetitions if the sum of the first number of consecutive delta values is greater than or equal to the predetermined threshold. For example, the aerosol-generating device 1 may reset the number of repetitions to zero.

In operation S1412, the aerosol-generating device 1 may determine whether the number of repetitions corresponds to a predetermined number of times. For example, the predetermined number of times may be preset to three.

In operation S1413, if the number of repetitions corresponds to the predetermined number of times, the aerosol-generating device 1 may perform at least one of increasing the first number and decreasing the predetermined threshold. For example, the aerosol-generating device 1 may change the first number to four if the first number is preset to three. For example, the aerosol-generating device 1 may reduce the predetermined threshold by a predetermined amount. Meanwhile, after performing at least one of increasing the first number and decreasing the predetermined threshold, the aerosol-generating device 1 may reset the number of repetitions.

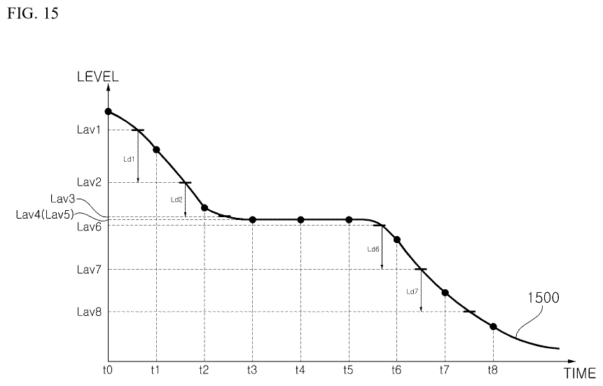

Referring to FIG. 15, a sensing value 1500 output from the stick detection sensor 133 may decrease as the capacitance of the insertion space increases while a part of the stick S is located in the insertion space. Meanwhile, in the state in which a part of the stick S is located in the insertion space, the remaining part of the stick S may be inserted after a certain time. For example, the user may adjust the position where the stick S is inserted so as to correspond to the heater C50 and then insert the remaining part of the stick S.

At this time, the sum of the first number of consecutive delta values Ld1, Ld2, and Ld3 may be less than the predetermined threshold, and the sum of the second number of consecutive delta values Ld1 to Ld7 may be greater than or equal to the predetermined threshold. Meanwhile, if the number of repetitions corresponds to the predetermined number of times and the predetermined threshold decreases, the sum of the first number of consecutive delta values Ld1, Ld2, and Ld3 may be greater than or equal to the changed threshold. As a result, the aerosol-generating device 1 may be more quickly powered on in response to the pattern of the user who uses the stick.

As described above, according to at least one of the embodiments of the present disclosure, it is possible to accurately determine the state of the stick S using sensing values of the sensor 133 that are periodically stored in the memory 17.

In addition, according to at least one of the embodiments of the present disclosure, it is possible to adjust the supply of power to the heater 18 based on the state of the insertion space into which the stick S is inserted.

In addition, according to at least one of the embodiments of the present disclosure, it is possible to optimize criteria for determining the state of the stick S based on the pattern of the user who uses the stick S.

Referring to FIGS. 1 to 15, an aerosol-generating device 1 according to an aspect of the present disclosure includes a body 10 having an insertion space formed therein, a heater configured to heat a stick S inserted into the insertion space, a sensor 133 configured to output a sensing value corresponding to the capacitance of the insertion space, a memory 17, and a controller 12, wherein the controller 12 stores the sensing value in the memory 17 according to a predetermined cycle, calculates a representative value of a plurality of consecutive sensing values stored in the memory 17, calculates a delta value, which is the difference between two consecutive representative values, determines whether the stick S is inserted based on the sum of a predetermined number of consecutive delta values, and in response to insertion of the stick S, adjusts the supply of power to the heater based on a change in the delta value.

In addition, in accordance with another aspect of the present disclosure, the controller 12 may calculate the average of two consecutive sensing values as the representative value.

In addition, in accordance with another aspect of the present disclosure, the controller 12 may calculate the sum of the delta values based on the magnitude of the delta value being greater than or equal to the minimum value.

In addition, in accordance with another aspect of the present disclosure, when the stick S is inserted, the controller 12 may adjust the supply of power to the heater based on a first temperature profile based on signs of the plurality of delta values being all the same, and may adjust the supply of power to the heater based on a second temperature profile based on the sign of at least one of the plurality of delta values being different from the sign of the rest.

In addition, in accordance with another aspect of the present disclosure, the controller 12 may power the aerosol-generating device 1 on based on the sum of a first number of first delta values being greater than or equal to a predetermined threshold and may determine that the stick S is inserted based on the sum of a second number of second delta values greater than the first number being greater than or equal to the predetermined threshold, and some of the second delta values may be the first delta values.

In addition, in accordance with another aspect of the present disclosure, the controller 12 may power the aerosol-generating device 1 on based on the sum of the second delta values being greater than or equal to the predetermined threshold while the sum of the first delta values is less than the predetermined threshold.

In addition, in accordance with another aspect of the present disclosure, the controller 12 may update the number of repetitions based on the sum of the second delta values being greater than or equal to the predetermined threshold while the sum of the first delta values is less than the predetermined threshold, and may perform at least one of increasing the first number and decreasing the predetermined threshold based on the number of repetitions corresponding to a predetermined number of times.

In addition, in accordance with another aspect of the present disclosure, the controller 12 may perform a preliminary operation for supplying power to the heater based on the aerosol-generating device 1 being powered on, and may adjust the supply of power to the heater in response to the insertion of the stick S based on the preliminary operation being completed.

In addition, in accordance with another aspect of the present disclosure, the controller 12 may store the sensing value in the memory 17 according to a first cycle in the state in which the stick S is removed, and may store the sensing value in the memory 17 according to a second cycle, which is shorter than the first cycle, in the state in which the stick S is inserted.

A method of operating an aerosol-generating device 1 according to an aspect of the present disclosure includes storing a sensing value corresponding to the capacitance of an insertion space in a memory 17 according to a predetermined cycle, calculating a representative value of a plurality of consecutive sensing values stored in the memory 17, calculating a delta value, which is the difference between two consecutive representative values, determining whether a stick S is inserted based on the sum of a predetermined number of consecutive delta values, and in response to insertion of the stick S, adjusting the supply of power to a heater 18 based on a change in the delta value.

As is apparent from the above description, according to at least one of the embodiments of the present disclosure, it is possible to accurately determine the state of the stick using sensing values of the sensor that are periodically stored in the memory.

According to at least one of the embodiments of the present disclosure, it is possible to adjust the supply of power to the heater based on the state of the insertion space into which the stick is inserted.

According to at least one of the embodiments of the present disclosure, it is possible to optimize criteria for determining the state of the stick based on the pattern of the user who uses the stick.

Certain embodiments or other embodiments of the disclosure described above are not mutually exclusive or distinct from each other. Any or all elements of the embodiments of the disclosure described above may be used in combination with each other or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The above detailed description should not be construed as being limiting in all respects but should be construed as being illustrative. The scope of the disclosure should be determined by a reasonable interpretation of the accompanying claims, and all changes within the equivalent scope of the disclosure are intended to be within the scope of the disclosure.

What is claimed is:

1. An aerosol-generating device comprising:
a body having an insertion space formed therein;
a heater configured to heat a stick inserted into the insertion space;
a sensor configured to output a sensing value corresponding to capacitance of the insertion space;
a memory; and
a controller configured to:
store the sensing value in the memory according to a predetermined cycle;
calculate a representative value of a plurality of consecutive sensing values stored in the memory;
calculate a delta value, which is a difference between two consecutive representative values;
determine whether the stick is inserted based on a sum of a predetermined number of consecutive delta values; and
in response to insertion of the stick, adjust a supply of power to the heater based on a change in the delta value.

2. The aerosol-generating device according to claim 1, wherein the controller is configured to calculate an average value of two consecutive sensing values as the representative value.

3. The aerosol-generating device according to claim 2, wherein the controller is configured to calculate the sum of the delta values based on a magnitude of the delta value being greater than or equal to a minimum value.

4. The aerosol-generating device according to claim 3, wherein, based on the stick being inserted, the controller is configured to:
adjust the supply of power to the heater based on a first temperature profile based on signs of the plurality of delta values being all the same; and
adjust the supply of power to the heater based on a second temperature profile based on the sign of at least one of the plurality of delta values being different from the sign of the rest.

5. The aerosol-generating device according to claim 3, wherein the controller is configured to:
power the aerosol-generating device on based on a sum of a first number of first delta values being greater than or equal to a predetermined threshold; and
determine that the stick is inserted based on a sum of a second number of second delta values that is greater than the first number being greater than or equal to the predetermined threshold,
some of the second delta values being the first delta values.

6. The aerosol-generating device according to claim 5, wherein the controller is configured to power the aerosol-generating device on based on the sum of the second delta values being greater than or equal to the predetermined threshold while the sum of the first delta values is less than the predetermined threshold.

7. The aerosol-generating device according to claim 6, wherein the controller is configured to:
update the number of repetitions based on the sum of the second delta values being greater than or equal to the predetermined threshold while the sum of the first delta values is less than the predetermined threshold, and
perform at least one of increasing the first number and decreasing the predetermined threshold based on the number of repetitions corresponding to a predetermined number of times.

8. The aerosol-generating device according to claim 6, wherein the controller is configured to:
perform a preliminary operation for supplying power to the heater based on the aerosol-generating device being powered on; and
adjust the supply of power to the heater in response to insertion of the stick based on the preliminary operation being completed.

9. The aerosol-generating device according to claim 1, wherein the controller is configured to:
store the sensing value in the memory according to a first cycle in a state in which the stick is removed; and
store the sensing value in the memory according to a second cycle that is shorter than the first cycle in a state in which the stick is inserted.

10. A method of operating an aerosol-generating device, the method comprising:
storing a sensing value corresponding to capacitance of an insertion space in a memory according to a predetermined cycle;
calculating a representative value of a plurality of consecutive sensing values stored in the memory;
calculating a delta value, which is a difference between two consecutive representative values;
determining whether a stick is inserted based on a sum of a predetermined number of consecutive delta values; and
in response to insertion of the stick, adjusting a supply of power to a heater based on a change in the delta value.
